(19) United States
(12) Patent Application Publication
(10) Pub. No.: US 2018/0331242 A1
(43) Pub. Date: Nov. 15, 2018

(54) Efficient Solar Energy Generation and Conversion System

(71) Applicant: Renewable Energy Solutions, Inc., Las Vegas, NV (US)

(72) Inventor: Travis Grimmett, Oceanside, CA (US)

(73) Assignee: Renewable Energy Solutions, Inc., Las Vegas, NV (US)

(21) Appl. No.: 15/974,481

(22) Filed: May 8, 2018

Related U.S. Application Data
(60) Provisional application No. 62/504,251, filed on May 10, 2017.

(51) Int. Cl. H01L 31/0475; G05F 1/67; H01L 31/05; H01L 31/053

(52) U.S. Cl. CPC H01L 31/0475; H01L 31/053; H01L 31/0504; G05F 1/67

(57) ABSTRACT

An advantageous system and method of converting solar energy from a photovoltaic (PV) array into alternating current (AC) for feeding into the electricity grid is described, which is based on the use of, in combination, multiple PV panels, a MPPT solar charger controller, an energy storage system, a motor speed controller, a DC motor, an induction generator, and a power electronic interface. Sets of PV panels are electrically connected in series forming multiple panel strings that are electrically connected in parallel to the MPPT solar charger controller that provides DC power for the energy storage devices. The motor speed controller controls the speed of the DC motor, which rotates the induction generator shaft at a rotational speed greater than the synchronous speed of the induction generator. The induction generator generates AC power that is transferred via the power electronic interface to the regulated AC power grid.

### CROSS-REFERENCE TO RELATED APPLICATIONS

This nonprovisional application claims the benefit of co-pending U.S. Provisional Patent Application Ser. No. 62/504,251 filed on May 10, 2017, which is incorporated herein in its entirety.

### FIELD OF INVENTION

This invention relates generally to systems for renewable energy generation and conversion, and, more particularly, to a system and method for improving energy generation and energy conversion from solar-generated DC power to grid-compliant AC power, which employs a photovoltaic solar panel array, an energy storage system, a MPPT solar charge controller, a motor controller, a DC motor, and an induction generator.

### BACKGROUND OF THE INVENTION

Renewable energy sources, particularly solar energy, are becoming increasingly important as the world realizes the many advantages. Currently the world relies heavily on fossil fuels, such as coal, oil, and natural gas, for its energy. Using fossil fuels draws on finite resources, which are becoming more expensive and damage the environment to retrieve. The use of renewable energy reduces the demand for fossil fuels and draws on a vast and inexhaustible energy supply, while simultaneously reducing carbon dioxide and other global warming emissions that can have harmful effects on human health. The International Energy Agency states that it expects solar power to become the world's largest source of electricity by 2050.

Within the solar energy family, photovoltaic (PV) systems are commonly used in distributed solar systems but may also be used in centralized multi-megawatt solar power plants. Solar energy has increased in popularity as PV systems have benefited from large price reductions in the cost of solar panels in the last few years. A typical PV panel is made up of mono crystalline or polycrystalline solar cells, which are series connected to form sub-strings to create 48-cell, 60-cell, and 72-cell modules or panels.

Distributed PV solar systems may be off-grid systems, which are not connected to the existing alternating current (AC) electric power grids (e.g., an AC power grid operated by an electric utility company). However most distributed PV systems are grid-connected systems that generate AC voltage independently of the power grid, and then transfer the independently generated AC power synchronously into the existing AC power grid for remuneration. These grid-connected PV systems typically use an inverter or multiple microinverters to convert the direct current (DC) power from the multiple solar panels to grid-compliant AC power, which is fed into the grid at the time it is produced.

Though conventional grid-connected PV systems are usable to convert renewable solar energy into grid-compliant AC power, there are disadvantages to these conventional PV systems. To optimize generation of AC power from renewable energy, efficiency is of upmost importance. Additionally, conventional PV systems only feed power into the grid during sunny conditions and only during peak operational hours (such as five to seven hours a day). It would be advantageous to provide a PV system that continuously feeds power into the grid—twenty-four hours a day and seven days a week, particularly while increasing the efficiency of energy conversion.

Accordingly, there is a need for a system and method for efficiently generating and converting energy from a renewable energy source, such as solar energy from a PV array, into grid-compliant AC power that is fed into the grid continuously.

### BRIEF SUMMARY OF THE INVENTION

The present invention is directed to an advantageous system and method of generating solar energy from a photovoltaic (PV) array and converting the generated energy into grid-compliant alternating current (AC) for feeding into the existing electricity grid based on the use of, in combination, multiple PV panels, a maximum power point tracking (MPPT) solar charger controller, an energy storage system, a motor speed controller, a DC motor, an induction generator, and a power electronic interface.

Sets of PV panels are electrically connected in series to form multiple PV panel strings, with the multiple panel strings electrically connected in parallel to a MPPT solar charger controller, preferably through a combiner box.

The MPPT solar charger controller optimizes the power output of the solar panel array; it is up to forty percent more efficient than standard pulse width modulator (PWM) controllers. The MPPT solar charger controller determines and supplies the correct voltage to optimize energy storage in the energy storage devices.

The motor speed controller obtains power from the batteries to drive the brushed DC motor. The DC motor rotates a shaft of the induction generator at a rotational speed which is greater than the synchronous speed of the induction generator, thereby allowing the induction generator to operate and generate AC power. This continually generated AC power from the induction generator is transferred by the power electronic interface to the regulated AC power grid. The generation of AC power from the solar renewable energy source is not limited to daylight hours, but can theoretically continue twenty-four hours a day, seven days a week. Additionally, the provided power generation system is highly efficient.

An object of the energy generation and conversion system of the present invention is to provide efficient power generation from a PV array.

Another object of the energy generation and conversion system of the present invention is to provide power conversion from DC power to AC power.

A further object of the energy generation and conversion system of the present invention is to continuously feed grid-compliant AC power into the power grid.

These and other objects, features, and advantages of the present invention will become more readily apparent from the attached drawings and from the detailed description of the preferred embodiments which follow.

### BRIEF DESCRIPTION OF THE DRAWING

The preferred embodiments of the invention will hereinafter be described in conjunction with the appended drawing, provided to illustrate and not to limit the invention.

FIG. 1 is a diagram of one embodiment of the present invention.

Like reference numerals refer to like parts throughout the drawing.

### DETAILED DESCRIPTION OF THE INVENTION

Shown throughout the FIGURES, the present invention is directed toward an efficient system and method of generating solar energy from a photovoltaic (PV) array and of converting the generated energy into grid-compliant alternating current (AC) for transfer to the electricity grid. This system, shown generally as reference number 10, comprises multiple PV panels 25 in a PV array 20, a maximum power point tracking (MPPT) solar charger controller 30, an energy storage system 40, a motor speed controller 50, a DC motor 60, an induction generator 70 (which is preferably an asynchronous generator), and a power electronic interface 80.

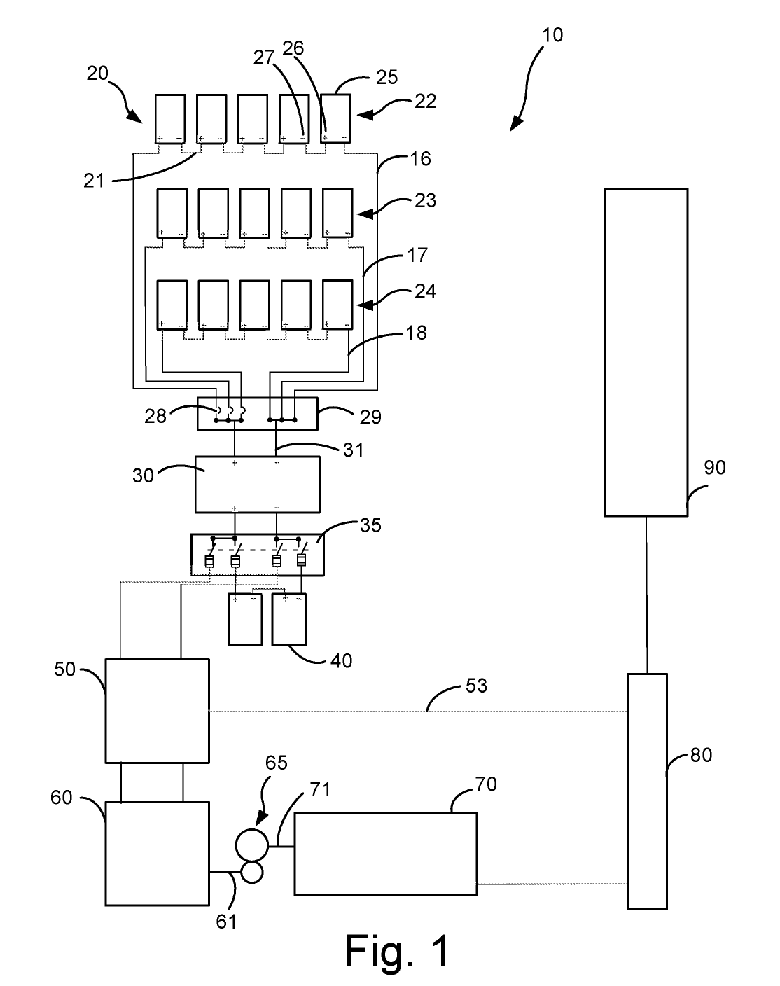

The PV array 20 comprises multiple PV panels 25 that directly convert solar energy to direct current (DC) electricity. These solar panels 25, which are typically installed on a frame assembly at a pre-determined angle, are electrically connected in series to increase the total voltage. The multiple PV panels 25 connected with series-type wiring form a PV string, shown as PV strings 22, 23, 24. To wire the PV panels 25 together in series, the positive terminal 26 of the first solar panel 25 is connected to the negative terminal 27 of the adjacent second one, the positive terminal 26 of the second solar panel 25 is connected to the negative terminal 27 of the adjacent third panel 25, and so on and so forth, until only a single positive and negative connection at opposing ends of the PV string is left. In the diagram of FIG. 1, the top five solar panels 25 are shown wired in series to form a first PV string 22; the middle five solar panels 25 are wired in series to form a second PV string 23; the lower five solar panels 25 are wired in series to form a third PV string 24.

To maximize the voltage output, the PV panels 25 are wired in series; to calculate the total voltage output, the voltages of the individual PV panels 25 in the string are summed. In an example, if the solar panels 25 of the first string 22 have a maximum power voltage rating of 30.8 volts at 8.75 amps and if there are five solar panels 25 in the series, the total output voltage of the entire string 22 would be 154 volts at 8.75 amps or 1,347.5 watts (volts*amps=watts). In this example, all the solar panels 25 are of the same type and power rating, which is preferred, but is not necessary to the invention.

Standard PV panels 25 as are known, or become known, in the art are employed in the energy generation and conversion system 10. A first non-limiting example of a suitable PV solar panel is Canadian Solar® CS6-P, which has a maximum power voltage of 30.8 V and a maximum power current of 8.75 A. A second non-limiting example of a suitable PV solar panel 25 is the Jinko® JKM255PP-V, which has a maximum power voltage of 30.8 V and a maximum power current of 8.28 A.

Each PV string 22, 23, 24 is connected in parallel to a combiner box 29. To connect one string, the single positive connection that remains after connecting the PV panels 25 in series is electrically connected via a positive conductor to a fuse terminal of the combiner box 29, and the single negative connection that remains after connecting the PV panel 25 series is electrically connected via a negative conductor to a fuse terminal of the combiner box 29.

The wiring used for connecting the PV panels 25 in series and for connecting the strings 22, 23, 24 to the combiner box will be selected based on code specifications and technical requirements, but a non-limiting example is #10 AWG copper wiring. In one aspect, the junction box of each solar panel 25 has two wires extending outwardly that end in corresponding male and female connectors to be used as quick connect devices between adjacent panels 25. Generally, the female connector is associated with the positive lead, and the male connector is associated with the negative lead. The complementary connectors may optionally include a locking mechanism to prevent unplugging or accidental disconnection.

The optional, but preferable, combiner box 29 serves to bring the output 16, 17, 18 of the multiple strings 22, 23, 24 together and to consolidate the incoming power into one main output 31. The combiner box 29 would also typically deliver overcurrent and undercurrent protection while providing a central location for easy installation, disconnection and maintenance. Optionally, but preferably, the combiner box 29 includes other features, such as a disconnect switch, monitoring equipment, arc-fault protection, and remote rapid shutdown.

The output conductor 31 connects the combiner box 29 to the MPPT solar charger controller. In one aspect, the MPPT solar charger controller may itself incorporate some of the features of the combiner box 29, and, therefore, no separate combiner box 29 would need to be used.

The MPPT solar charger controller 30 is an electronic DC to DC converter that optimizes the match between the PV panels 25 and the battery energy storage system 40. This is done by determining the voltage output of the PV panels 27, the voltage of the batteries 40, and the maximum power point using a known maximum power point algorithm. The controller 30 then does a voltage/current conversion to provide the battery with the optimum voltage for energy storage. Generally, the higher voltage DC output from the PV panels 25 is converted down to a lower voltage that is optimal for charging the batteries 40. The MPPT controller 30 continuously optimizes the charging of the batteries 40; the use of the MPPT solar charger controller 30 has been shown to increase power gain up to 40% in winter and up to 15% in summer compared to a pulse-width modulation (PWM) controller. The power gain varies based on factors such as weather, temperature, and the battery state of charge.

The MPPT solar charger controller 30 also provides DC power to the motor speed controller 50. Preferably the controller 30 has integrated safety features. And preferably the controller 30 has communication hardware allowing remote viewing of controller report data and providing remote control access. Any of a variety of MPPT solar charger controllers 30 may be utilized in the system 10. A non-limiting example of a suitable controller 30 is the Midnight Solar Inc.® model Classic200, which has a maximum operating voltage of 250 V, provides a battery charge voltage of 12 to 93 volts, provides secure data monitoring and data logging with onboard storage, can be remotely accessed via the Internet, and includes two auxiliary outputs to divert excess power to other applications, such as battery box vents or generator 70 starting.

The MPPT solar charger controller 30 is preferably connected to the batteries 40 through a safety disconnect 35 having the specifications required by the manufacturer. The energy storage system is comprised of one or multiple higher-capacity rechargeable batteries 40. The batteries 40 store the solar energy captured during the day to be used during AC generation at night. The batteries are preferably deep-cycle lead-acid batteries that are designed to be regularly deeply discharged, such as being discharged from 45% to 80% of capacity (depending on the specifications of the particular battery). Optionally, other batteries 40, as are known or become known in the art, may be used. For example, lithium-ion polymer batteries are much lighter, but are currently less economical. A non-limiting example of a suitable battery is a 36-volt or 48-volt Great Lakes® forklift-type battery with a 20 ampere-hour (AH) AH rating This battery and similar batteries are specifically designed for use with solar power generation systems and can be discharged steadily over a number of hours, such as up to 20 hours.

The motor speed controller 50 is a controller that draws on the power from the batteries 40 to provide the proper DC current to the electric motor 60 to allow the DC electric motor 60 to continually rotate its output shaft 61 at a speed (RPM) that is greater than the synchronous speed of the induction generator 70, even as the batteries 40 are being depleted, up to the point at which the batteries 40 have reached a depletion level at which the motor speed controller 50 can no longer provide sufficient power or, preferably, up to the depth of discharge recommended by the battery manufacturer. Though there is a battery depletion limit, the components of the efficient solar energy generation system 10 of the present invention are selected so that the batteries 40 store a sufficient amount of power to allow the motor speed controller 50 to output the designated DC current to the motor 60 continually, routinely continuing through the night when there is no incoming solar power.

In one aspect of the invention, the motor speed controller 50 provides power 53 to components of the power electronic interface 80. The motor speed controller 50 is preferably programmable; it may also include an ethernet interface that allows viewing of output data and configuration through a web browser. It may have a peak of around 40 to 60 HP. A non-limiting example of a suitable motor speed controller 50 is a 600-amp Alltrax® SR Series motor controller.

The power output from the motor speed controller 50 drives the brushed DC motor 60 to rotate its output shaft 61 at a substantially constant rotational speed. Shaft 61 is coupled by a mechanical coupling 65 to a shaft 71 of the induction generator 70 so that when shaft 61 rotates, shaft 71 is rotated. In one aspect, mechanical coupling 65 may be a flexible coupling.

The DC motor 60 rotates shaft 61 at a rotational speed greater than the synchronous speed of the induction generator 70, thereby permitting the power generated by induction generator 70 to be synchronized properly into the utility grid 90. In this configuration, the power drain from the batteries 40 and from the solar array 20 can be adjusted by motor speed controller 50 as needed for optimal efficiency with relatively small changes in speed, as the power is transferred efficiently through the system. In a typical induction generator 70 that is used in the current efficient solar energy generation and conversion system 10, such a speed would likely be above 1200 RPM. In an example, in which the asynchronous speed is 1,200 RPM, the rotational speed of the motor shaft 61 and of the coupled generator shaft 71 may be 1,249 RMP, which will produce 20 KW per hour. A non-limiting example of a suitable DC motor is the NetGain Motors, Inc. ImPulse 9™ DC motor.

The induction generator 70 may be a single-phase induction generator, but a multi-phase induction generator (for example, a three-phase induction generator) is preferred. The induction generator 70 includes a rotating element or rotor and a stationary element or stator. The rotor is formed preferably of an aluminum or copper “squirrel cage” mounted on shaft 71. The stator is formed of insulated copper windings within the stator laminations. When shaft 71 is forced to rotate at a speed higher than synchronous, the stator magnetic field vector accepts power induced from the rotor as the squirrel cage is sweeping the field vector, causing a flux reversal and the generation of AC current, which can then be supplied in proper synchrony to the power grid 90. A non-limiting example of a suitable induction generator 70 is the Primeline® Marathon electric two-bearing induction generator having a rating of 21 KW.

In another aspect, a single shaft may join the induction generator 70 and the DC motor 60, with the single shaft performing the functions of the coupled motor shaft 61 and the generator shaft 71. In a further aspect, the DC motor 60, single shaft, and induction generator 70 may be disposed in a single housing.

The induction generator 70 continually generates AC power that is transferred to the regulated AC power grid 90 through the power electronic interface 80. The power electronic interface 80 preferably includes sensors and measurement devices to monitor the flow of AC power and that may automatically shut down the system 10 if the utility grid 90 fails. Preferably the induction generator 70 includes hardware and software providing control and data viewing access, such as through a web-based browser.

Optionally, one or more of the components of the solar energy generation and conversion system 10 may be configured with a communication gateway to allow the one or more components to connect to a communications network either through wired or wireless connections. Control circuitry may control these one or more components via the communications network.

In addition, particularly upon multiple installations of the energy generation and conversion system 10 as described above, the system 10 may be expanded to include software and hardware that provide monitoring and control features. This will allow a user to remotely monitor the generation portion of the system and the conversion portion of the system and to remotely troubleshoot problems, to stop, and to restart the system.

Using this efficient energy generation and conversion system 10, the renewable energy from the sun is used to generate DC energy, so that even when the sun is not shining, the motor speed controller 50 can be powered by the stored energy to drive the DC motor 60 to turn the shaft 71 of the induction generator 70, thus generating AC power, which is passed into the pre-existing grid. Therefore, the renewable energy system 10 is theoretically capable of continuously generating grid-compliant AC power, twenty-four hours a day, seven days a week.

Though the energy generation and conversion system 10 of the current invention has been described herein using solar energy as the renewable energy source, the energy generation and conversion system 10 is usable with minor modifications with other sources of renewable energy, such as wind energy. The wind energy is used to generate the power stored in the batteries 40, and the remainder of the energy generation and conversion system 10 may be used to produce grid-compliant AC power.

Since many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalents.

What is claimed is:

1. A photovoltaic (PV) power system, comprising:
multiple PV panels connected in a series to form multiple strings;
a maximum power point tracking (MPPT) solar charger controller electrically connected to said multiple PV panels; wherein output power of said MPPT solar charger controller is DC power;
an energy storage system electrically coupled to said MDDT solar charger controller;
a motor speed controller electrically coupled to said energy storage system, wherein output power of said motor speed controller is DC power;
a DC motor having an output shaft and being electrically coupled to said motor speed controller;
an induction generator operatively coupled to said DC motor and outputting induced AC power; and
a power electronic interface connecting said induction generator to a regulated AC power grid.
